(19) United States
(12) Patent Application Publication
(10) Pub. No.: US 2023/0026424 A1
(43) Pub. Date: Jan. 26, 2023

(54) IMMERSION COOLING OF INFORMATION HANDLING SYSTEMS WITH ON-NODE BOOST PUMPS

(71) Applicant: Dell Products, L.P., Round Rock, TX (US)

(72) Inventors: Robert Boyd Curtis, Georgetown, TX (US); Shawn Paul Hoss, Georgetown, TX (US); David L. Moss, Austin, TX (US); Dominick Adam Lovicott, Jarrell, TX (US)

(73) Assignee: Dell Products, L.P., Round Rock, TX (US)

(21) Appl. No.: 17/380,944

(22) Filed: Jul. 20, 2021

(51) Int. Cl. H05K 7/20

(52) U.S. Cl. CPC H05K 7/20236; H05K 7/20254; H05K 7/20272; H05K 7/20172

(57) ABSTRACT

Information handling system (IHS) component immersion cooling systems and methods may employ a cold plate disposed on one or more IHS components of an IHS disposed in an immersion cooling tank and an immersible immersion fluid pump adapted to be deployed in the immersion cooling tank, the immersible immersion fluid pump in fluid flow communication with the cold plate, directing flow of immersion fluid in the immersion cooling tank to the cold plate. The immersible immersion fluid pump may be disposed on the cold plate or in an equipment bay of the IHS. A manifold may distribute flow from first and/or second immersible immersion fluid pump(s) to first and second cold plates. Power, etc. may be provided to the immersible immersion fluid pump via (a) fan connection(s) provided by the IHS. Tubing may extend from an outlet of the cold plate away from other components of the IHS.

### FIELD

This disclosure relates generally to Information Handling Systems (IHSs), and more specifically, to IHS immersion cooling with node pumping.

### BACKGROUND

As the value and use of information continue to increase, individuals and businesses seek additional ways to process and store information. One option is an Information Handling System (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated.

The variations in IHSs allow for IHSs to be general or configured for a specific user, or for a specific use such as financial transaction processing, airline reservations, enterprise data storage, global communications, etc. In addition, IHSs may include a variety of hardware and software components that may be configured to process, store, and communicate information and may include one or more computer systems, data storage systems, and networking systems.

Typically, IHSs are designed for air cooling. Conventional IHSs (e.g., servers, etc.) usually comprise one or more printed circuit boards having a plurality of electrical components mounted thereon—these printed circuit boards are housed in an enclosure having vents that allow external air to flow into the enclosure, and then out of the enclosure after being routed internally through the enclosure for cooling the IHS. In many instances, a fan is also located within the enclosure to facilitate this airflow.

In general, a lower air temperature allows each IHS component to dissipate more power and therefore operate at a level of hardware performance. Consequently, IHS facilities (e.g., data centers, etc.) have used sophisticated air conditioning systems to cool the air within it for achieving a desired performance level. As energy costs and power dissipation continue to increase, however, the total cost of cooling these facilities has also increased.

As an alternative to air cooling, immersion cooling of IHSs (e.g., in a dielectric liquid coolant, as opposed to air) may be employed. Immersion cooling has the potential of becoming a popular server cooling solution as it enables elimination of air cooling infrastructure, and the like, including on-board server fans, computer room air conditioning, compressors, air-circulation fans, necessary duct work, air handlers, and other active ancillary systems such as dehumidifiers. These systems are replaced with one or more low speed liquid circulation pumps, a heat exchanger, and/or the like.

### SUMMARY

Embodiments of immersion cooling of Information Handling Systems (IHSs) with on-node boost pumps are described. In an illustrative, non-limiting embodiment, an IHS may include an IHS component immersion cooling systems and methods that employ a cold plate disposed on one or more IHS components of an IHS disposed in an immersion cooling tank and an immersible immersion fluid pump adapted to be deployed in the immersion cooling tank, the immersible immersion fluid pump in fluid flow communication with the cold plate, directing flow of immersion fluid in the immersion cooling tank to the cold plate. The immersible immersion fluid pump may be disposed on the cold plate or in an equipment bay of the IHS, such as a fan bay. A manifold may distribute flow from first and/or second immersible immersion fluid pump(s) to first and second cold plates. Tubing may extend from an outlet of the cold plate away from other components of the IHS. Existing IHS fan connectors for power, pulse width modulation and tach monitoring may provide power, pulse width modulation and tach monitoring of the immersible immersion fluid pump(s).

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity, and have not necessarily been drawn to scale.

FIG. 1 is a diagrammatic illustration of an example of immersion fluid flow in a prior art immersion Information Handling System (IHS) cooling system.

FIG. 2 is a diagrammatic illustration of an example prior art IHS adapted for use in a prior art immersion IHS cooling system.

FIG. 3 is a diagrammatic illustration of an example IHS employing on-node boost pump IHS component immersion cooling, in accordance with some embodiments of the present systems and methods.

FIG. 4 is a diagrammatic illustration of an example IHS employing on-node boost pump IHS component immersion cooling, in accordance with some other embodiments of the present systems and methods.

FIG. 5 is a diagrammatic illustration of an example IHS employing on-node boost pump IHS component immersion cooling, in accordance with some further embodiments of the present systems and methods.

FIG. 6 is a diagrammatic illustration of an example of improved IHS immersion fluid flow, according to some embodiments of the present systems and methods.

FIG. 7 is a diagram of an example of an IHS according to some embodiments.

### DETAILED DESCRIPTION

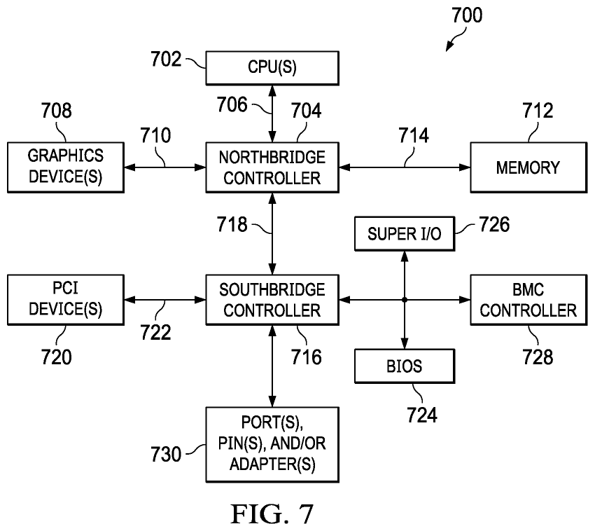

For purposes of this disclosure, an IHS may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a personal computer (e.g., desktop or laptop), tablet computer, mobile device (e.g., Personal Digital Assistant (PDA) or smart phone), server (e.g., blade server or rack server), a network storage device, or any other suitable device and may vary in size, shape, performance, functionality, and price. However, embodiments of the present systems and methods are practically adapted with respect to servers, switches, network storage devices and/or the like, which may be cooled using immersion cooling. An IHS may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. An IHS may also include one or more buses operable to transmit communications between the various hardware components. A more detailed example of an IHS is described with respect to FIG. 7.

In existing IHS immersion cooling implementations where the tank pump module pumps bulk flow into the tank, flow through the IHSs disposed in the tank, such as may be referred to herein as compute “nodes,” or the like, is determined only by the total flow rate and impedance of the individual hardware nodes installed in the tank. Existing IHS immersion cooling tanks have no mechanism for controlling flow through each hardware node. Cooling limitations arise at the CPU (and other areas), particularly in fully populated IHS immersion cooling tanks.

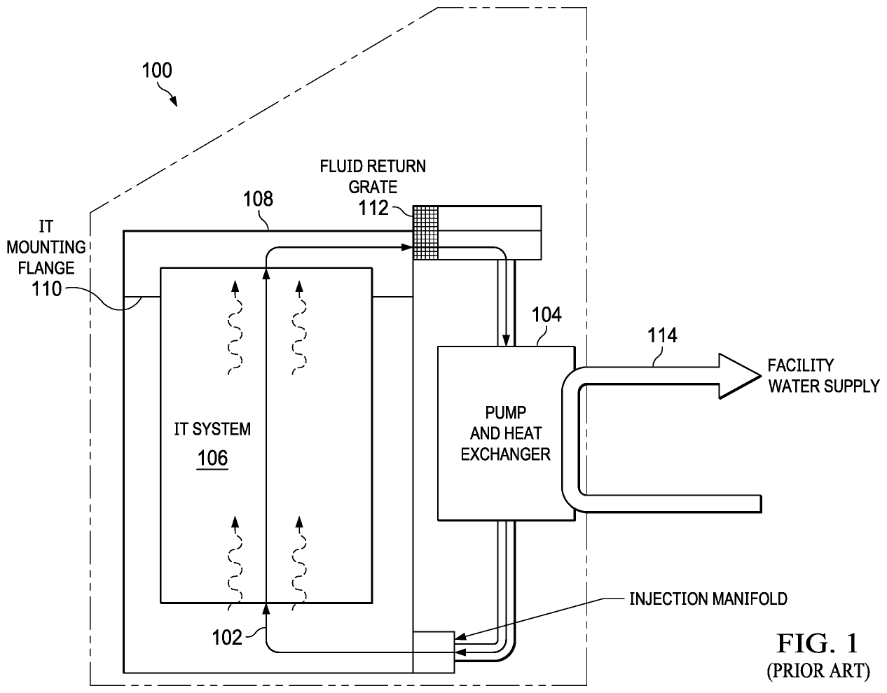

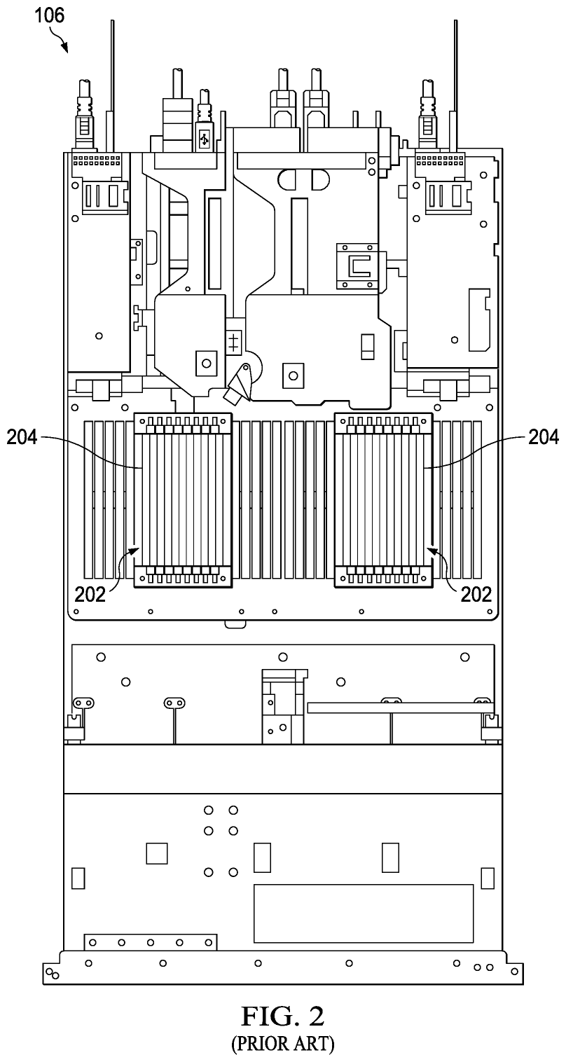

FIG. 1 is a diagrammatic illustration of example immersion fluid flow in prior art immersion IHS cooling system 100. Therein, bulk flow 102 provided by tank pump or pumping module 104 typically results in no control of flow to each node 106 within the tank and no direction of flow directly to a CPU or other high power component(s) in a node. FIG. 2 is a diagrammatic illustration of example prior art IHS 106 adapted for use in a prior art immersion IHS cooling system, such as system 100 of FIG. 1. IHS 106, which may be referred to as a “node,” or the like may employ “oil optimized” heatsink 202, deployed on a CPU, or the like. Such an oil optimized heatsink 202 typically has with fewer fins 204, compared to an air cooled heat sink, for example, to help increase immersion fluid flow through (i.e., across) the heatsink.

In various embodiments, system 100 may be capable of cooling one or more IHSs 106 containing heat-generating components by reducing the temperature difference between heat generating or dissipating components, and an “immersion fluid” used to cool those components. As used herein, the term “immersion fluid” includes a liquid coolant that may be any non-conductive liquid such that electrical components of an IHS (e.g., a motherboard, a memory, CPU, and other electrical and/or electronic components designed for use in air) continue to operate reliably while submerged without significant modification. In some embodiments, a suitable immersion fluid is a “single phase” dielectric liquid coolant, including for example vegetable oil, mineral oil (e.g., transformer oil), etc.

System 100 includes tank 108 containing a dielectric immersion fluid into which a plurality of IHSs may be immersed or submerged. A rack or mounting flange 110 is positioned within tank 108 and is configured to receive and mount the plurality of IHSs 106 into tank 108. Tank 108 may have an opening, such as an open top, for access to each of IHSs 106 mounted in flange 110. At least a portion of each IHS 106 is submerged within the dielectric immersion fluid for cooling each respective IHS when tank 108 is sufficiently full of the immersion fluid. In various embodiments, each of IHSs 106 is completely submerged within the dielectric immersion fluid during their normal operation.

The immersion fluid heated by IHSs 106 in flange 110 is coupled, through grated fluid return 112, or the like to piping or lines to a pump, which may be integrated with a heat exchanger, as illustrated as 104, which pumps heated immersion fluid from tank 108 for heat-rejection or cooling such as through the use of facility water supplied at 114. The cooled immersion fluid through a fluid supply line or piping back into tank 108.

Thus, in existing IHS immersion cooling implementations where the tank pump module pumps bulk flow into the tank, flow through the compute nodes is determined only by the total flow rate and impedance of the individual hardware nodes installed in the tank. Existing IHS immersion cooling tanks have no mechanism for controlling flow through each hardware node Existing tanks have no mechanism for controlling flow through each hardware node or for controlling flow within the immersed hardware. Cooling limitations arise at IHS CPUs (and other areas), particularly in fully populated IHS immersion cooling tanks.

In accordance with embodiments of the present systems and methods, IHS immersion cooling with node pumping integrate an immersed pump within a node to provide active pumping at the node CPU (or for other high power component(s)). In accordance with such embodiments, heatsinks are replaced with a cold plate solution designed for single phase immersion fluids and a pump is connected to force flow through the cold plate. In these embodiments, the node pump is coupled to a cold plate, such as may be designed for oil immersion fluids and optimized for CPU cooling, to thereby increase cooling capability of oil immersion IHSs. Flow through such cold plates may utilize impingement, or cross flow designs, to best optimize cooling of the IHS component. These node integrated pumps direct flow directly to cold plates in an immersion cooling implementation. Increased flows through each hardware node and/or forced flow directed directly at the IHS component will increase cooling capabilities at the IHS component. Other high power components, such as Graphics Processing Unit (GPU) or any other thermal limiting component, may also benefit from such increased (directed) flows through each hardware node and/or forced flow directed directly at the high power component(s), as well. These node integrated pumps increase the overall flow into the node thus benefiting the cooling of node components upstream of the pumps.

Since the pumps are immersed in the fluid there is no need for tubing to provide flow to an inlet of the pump. The pumps may pull immersion fluid directly from the tank and push it through the cold plate. Also, in various embodiments tubing may not be required at the outlet of the cold plate. Outlet fluid may be blended with the immersion fluid in the tank upon exit from the cold plate. However, in some embodiments, Tubing from a cold plate may be included, such as, if needed to direct hot fluid away from downstream components (e.g., directing fluid to toward the top of the tank rather than exhausting onto downstream devices such as Peripheral Component Interconnect Express (PCIe) (riser) cards, a power supply unit, storage devices, or the like). The pumps within a server, switch, or storage node may plug directly into the existing fan connectors for power, Pulse Width Modulation (PWM) and tach monitoring. Pumping power requirements in accordance with embodiments of the present systems and methods are much lower than typical system fan requirements. Pumps can also be configured for redundancy in the event of a pump failure. In such embodiments, pumps may, each, direct flow into a manifold, tubing system, or the like, which distributes flow to the cold plates, in accordance with the present systems and methods.

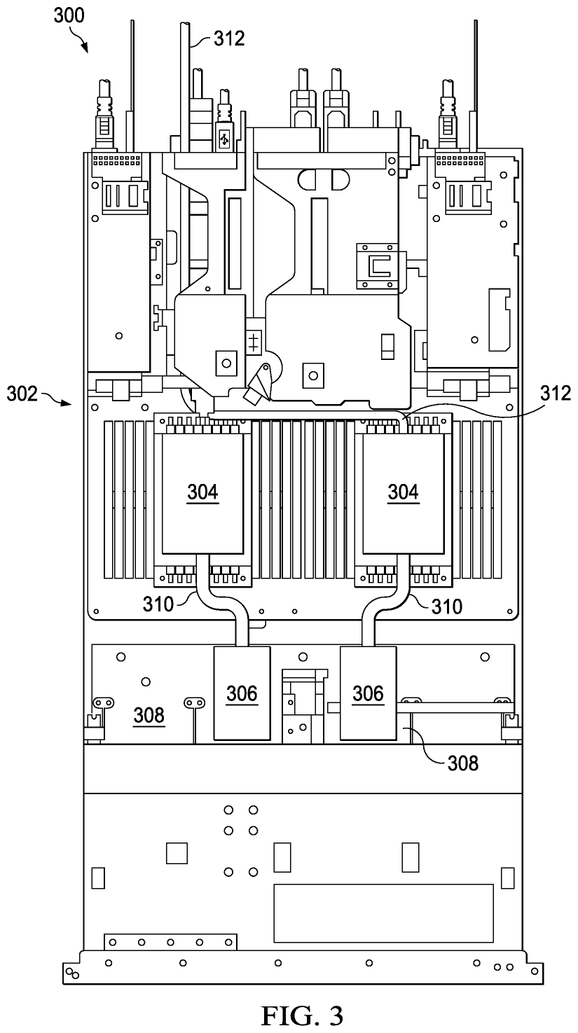

FIGS. 3 through 5 are diagrammatic illustration of example IHSs 300, 400 and 500, respectively, employing on-node boost pump IHS component immersion cooling, in accordance with various embodiments of the present systems and methods.

In FIG. 3 IHS 300 includes chassis 302 configured to be at least partially disposed under a surface of an immersion fluid, the chassis mounts various components configured to be cooled by immersion fluid, such as in an immersion cooling tank, during operation of the IHS. Cold plate 304 is disposed on one or more of these components to be cooled, such as a CPU of IHS 300, as illustrated. One or more immersible immersion fluid pumps 306, which have been selected and/or adapted to be deployed in the immersion fluid in the cooling tank are deployed in conjunction with cold plate(s) 304. In the embodiment of FIG. 3, immersible immersion fluid pump(s) 306 is (are) disposed in (an) equipment bay(s), such as (a) fan bay(s) 308 of IHS 300. Immersible immersion fluid pump(s) 306 is (are) in fluid flow communication with cold plate(s) 304, such as via illustrated conduit 310. Immersible immersion fluid pump(s) 306 direct(s) flow of immersion fluid, drawn from within the immersion cooling tank to cold plate(s) 304, such as via illustrated conduit(s) 310. Power to immersible immersion fluid pump(s) 306, IHS control of immersible immersion fluid pump(s) 306, and/or monitoring of immersible immersion fluid pump(s) 306 by IHS 300, may be provided via respective fan power connection(s), (a) fan PWM connection(s), and/or (a) tach monitoring connection(s) provided by the IHS. For example, pump(s) 306 may plug into existing fan headers (not shown) for power, PWM control, tach monitoring, or the like. In accordance with some embodiments of the present systems and methods, tubing 312, or the like may be used to direct hot exhaust fluid from cold plate so that the hot fluid does not negatively impact the cooling of downstream components. For example, tubing 312 extending from an outlet of cold plate(s) 304, away from other components of the IHS may be used to implement such embodiments. Such further embodiments may be implemented as needed, with respect to particular IHSs and/or in particular tank deployments (of a subject IHS).

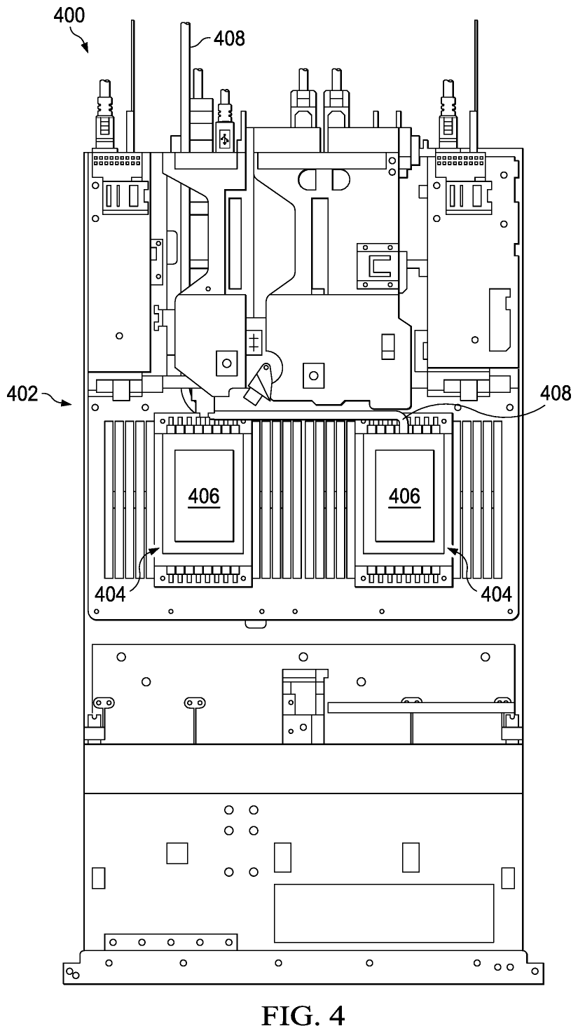

In FIG. 4 IHS 400 includes chassis 402 configured to be at least partially disposed under a surface of an immersion fluid, the chassis mounts various components configured to be cooled by immersion fluid, such as in an immersion cooling tank, during operation of the IHS. Cold plate 404 is disposed on one or more of these components to be cooled, such as a CPU of IHS 400, as illustrated. One of immersible immersion fluid pumps 406, which have been selected and/or adapted to be deployed in the immersion fluid in the cooling tank, is deployed in conjunction with each cold plate 404. In the embodiment of FIG. 4, each immersible immersion fluid pump 406 is disposed on a respective cold plate 404. Immersible immersion fluid pump 406 is in fluid flow communication with the respective cold plate and directs flow of immersion fluid, drawn from within the immersion cooling tank, to and through respective cold plate 404. Power to immersible immersion fluid pump(s) 406, IHS control of immersible immersion fluid pump(s) 406, and/or monitoring of immersible immersion fluid pump(s) 406 by IHS 400, may be provided via respective fan power connection(s), (a) fan PWM connection(s), and/or (a) tach monitoring connection(s) provided by IHS 400. For example, pump(s) 406 may plug into existing fan headers (not shown) for power, PWM control, tach monitoring, or the like. Also, in accordance with some embodiments of the present systems and methods, tubing 408, or the like, extending from an outlet of cold plate 404 may be used to direct hot exhaust fluid from cold plate 404, away from other components of the IHS so that the hot fluid does not negatively impact the cooling of downstream components. Such further embodiments may be implemented as needed, with respect to particular IHSs and/or in particular tank deployments (of a subject IHS).

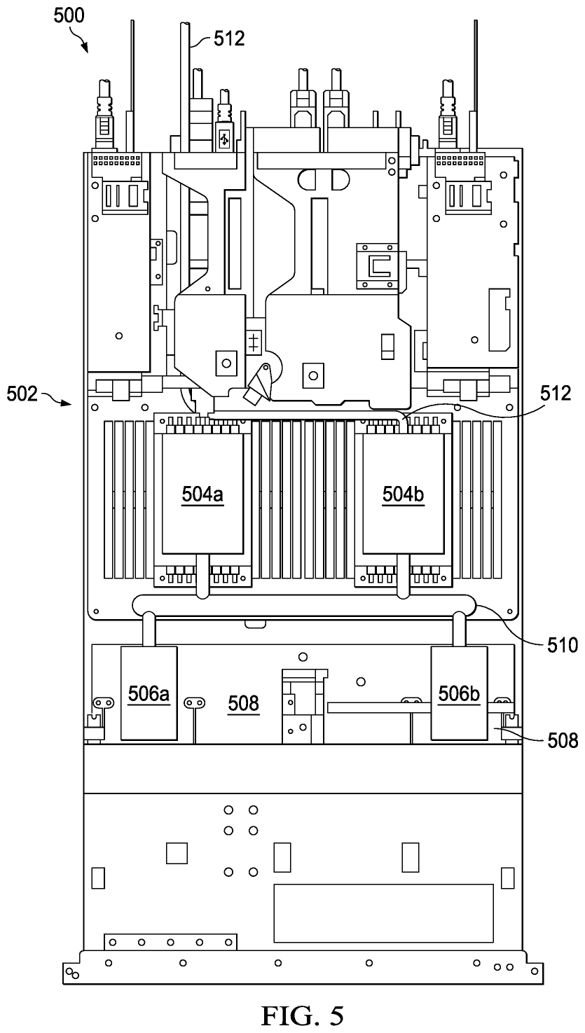

In FIG. 5 IHS 500 includes chassis 502 configured to be at least partially disposed under a surface of an immersion fluid, the chassis mounts various components configured to be cooled by immersion fluid in an immersion cooling tank during operation of the IHS. Cold plates 504a, 506b, etc. are each disposed on one or more of these components to be cooled, such as CPUs of IHS 500, as illustrated. A plurality of immersible immersion fluid pumps 506a, 506b, etc., which have been selected and/or adapted to be deployed in the immersion fluid in the cooling tank are deployed in conjunction with cold plates 504a, 506b, etc. In the embodiment of FIG. 5, immersible immersion fluid pumps 506a, 506b, etc. are disposed in one or more equipment bays, such as fan bays 508 of IHS 500. Immersible immersion fluid pumps 506a, 506b, etc. are in fluid flow communication with cold plates 504a, 504b, etc., such as via illustrated manifold 510 In accordance with such embodiments of the present systems and methods, pumps 506a, 506b, etc. may be configured for redundancy via internal tubing, illustrated manifold 510, or the like, connected to each cold plate 504a, 504b, etc. Such internal tubing, illustrated manifold 510, or the like, is adapted to distribute flow from the immersible immersion fluid pumps 506a, 506b, etc. to cold plates 504a, 504b, etc. Thereby, immersible immersion fluid pump(s) 506a, 506b, etc. direct flow of immersion fluid, drawn from within the immersion cooling tank, to cold plates 504a, 504b, etc. Power to immersible immersion fluid pumps 506a, 506b, etc., IHS control of immersible immersion fluid pumps 506a, 506b, etc., and/or monitoring of immersible immersion fluid pumps 506a, 506b, etc., may be provided via (a) respective fan power connection(s), (a) fan PWM connection(s), and/or (a) tach monitoring connection(s) provided by the IHS. For example, pumps 506a, 506b, etc. may plug into existing fan headers (not shown) for power, PWM control, tach monitoring, or the like. In accordance with some embodiments of the present systems and methods, tubing 512, or the like may be used to direct hot exhaust fluid from one or more of cold plates 504a, 504b, etc., so that the hot fluid does not negatively impact the cooling of downstream components. For example, tubing 512, or the like, extending from an outlet of one or more of cold plate(s) 504a, 504b, etc., away from other components of the IHS may be used to implement such embodiments. Such further embodiments may be implemented as needed, with respect to particular IHSs and/or in particular tank deployments (of a subject IHS).

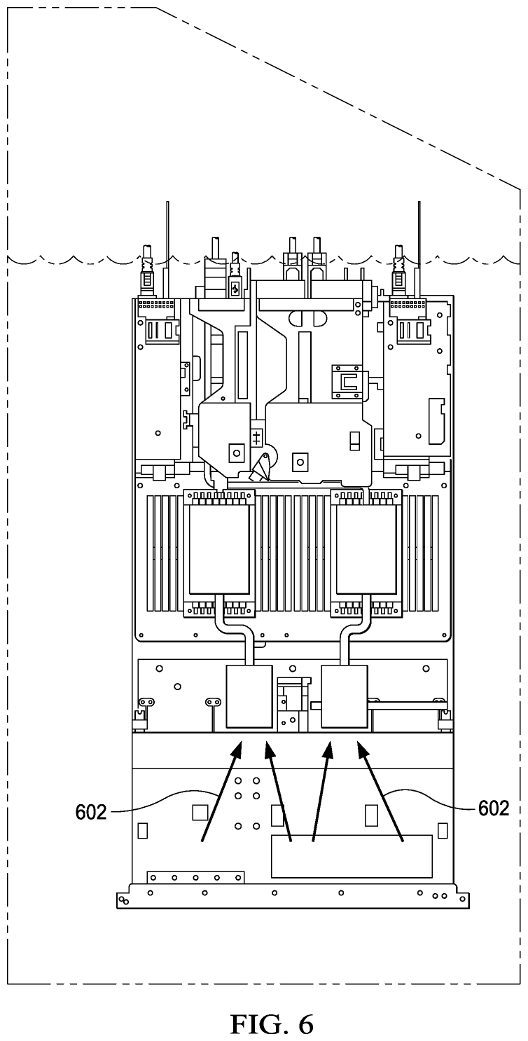

FIG. 6 is a diagrammatic illustration of an example of improved IHS immersion fluid flow 602, according to some embodiments of the present systems and methods. FIG. 6 shows immersion fluid flow in an immersion cooling tank, wherein example IHS 300 (of FIG. 3) is employing on-node boost pump IHS component immersion cooling, as an example, in accordance with various embodiments of the present systems and methods, such as described above. In accordance with the various described implementations of the present systems and methods, net flow through the node (i.e., the IHS) is increased due to the pumps forcing flow through the cold plates. This increase in flow results in more fluid entering the node below the pumps, as shown in FIG. 6, at 602. Thus, increased flow 602 through the IHS (i.e., a server) results in improved cooling for the components, particularly in the illustrated front of the IHS. IHS, and/or immersion cooling system, architectures may be designed to take advantage of increased flow 602, e.g., locating components near or in the path to the pumps or directing flow 602 to the pumps so that it passes over components that will benefit from the added flow rate.

FIG. 7 is a diagram of an example of IHS 700 which may be cooled within tank 101 of system 100. As shown, IHS 700 includes one or more CPUs 702. In various embodiments, IHS 700 may be a single-processor system including one CPU 702, or a multi-processor system including two or more CPUs 702 (e.g., two, four, eight, or any other suitable number). CPU(s) 702 may include any processor capable of executing program instructions. For example, in various embodiments, CPU(s) 702 may be general-purpose or embedded processors implementing any of a variety of instruction set architectures (ISAs), such as the x86, POWERPC, ARM, SPARC, or MIPS ISAs, or any other suitable ISA. In multi-processor systems, each of CPU(s) 702 may commonly, but not necessarily, implement the same ISA. In an embodiment, a motherboard (not shown) may be configured to provide structural support, power, and electrical connectivity between the various components illustrated in FIG. 7.

CPU(s) 702 are coupled to northbridge controller or chipset 704 via front-side bus 706. Northbridge controller 704 may be configured to coordinate I/O traffic between CPU(s) 702 and other components. For example, in this particular implementation, northbridge controller 704 is coupled to graphics device(s) 708 (e.g., one or more video cards or adaptors, etc.) via graphics bus 710 (e.g., an Accelerated Graphics Port or AGP bus, a Peripheral Component Interconnect or PCI bus, etc.). Northbridge controller 704 is also coupled to system memory 712 via memory bus 714. Memory 712 may be configured to store program instructions and/or data accessible by CPU(s) 702. In various embodiments, memory 712 may be implemented using any suitable memory technology, such as static RAM (SRAM), synchronous dynamic RAM (SDRAM), nonvolatile/Flash-type memory, or any other type of memory.

Northbridge controller 704 is coupled to southbridge controller or chipset 716 via internal bus 718. Generally, southbridge controller 716 may be configured to handle various of IHS 700's I/O operations, and it may provide interfaces such as, for instance, Universal Serial Bus (USB), audio, serial, parallel, Ethernet, etc., via port(s), pin(s), and/or adapter(s) 730 over bus 724. For example, southbridge controller 716 may be configured to allow data to be exchanged between IHS 700 and other devices, such as other IHSs attached to a network. In various embodiments, southbridge controller 716 may support communication via wired or wireless general data networks, such as any suitable type of Ethernet network, for example, via telecommunications/telephony networks such as analog voice networks or digital fiber communications networks; via storage area networks such as Fiber Channel SANs; or via any other suitable type of network and/or protocol.

Southbridge controller 716 may also enable connection to one or more keyboards, keypads, touch screens, scanning devices, voice or optical recognition devices, or any other devices suitable for entering or retrieving data. Multiple I/O devices may be present in IHS 700. In some embodiments, I/O devices may be separate from IHS 700 and may interact with IHS 700 through a wired or wireless connection. As shown, southbridge controller 716 is further coupled to one or more PCI devices 720 (e.g., modems, network cards, sound cards, video cards, etc.) via PCI bus 722, including, for example, self-encrypting Hard Disk Drives (HDDs) or Solid State Drives (SSDs). Southbridge controller 716 is also coupled to Basic I/O System (BIOS) 724, Super I/O Controller 726, and Baseboard Management Controller (BMC) 728 via Low Pin Count (LPC) bus 720.

BIOS 724 includes non-volatile memory having program instructions stored thereon. Those instructions may be usable CPU(s) 702 to initialize and test other hardware components and/or to load an Operating System (OS) onto IHS 700. As such, BIOS 724 may include an interface that allows CPU(s) 702 to load and execute certain firmware. In some cases, such firmware may include program code that is compatible with the Unified Extensible Firmware Interface (UEFI) specification, although other types of firmware may be used.

BMC controller 728 may include non-volatile memory having program instructions stored thereon that are usable by CPU(s) 702 to enable remote management of IHS 700. For example, BMC controller 728 may enable a user to discover, configure, and manage BMC controller 728, setup configuration options, resolve and administer hardware or software problems, etc. Additionally, or alternatively, BMC controller 728 may include one or more firmware volumes, each volume having one or more firmware files used by the BIOS' firmware interface to initialize and test components of IHS 700.

Super I/O Controller 726 combines interfaces for a variety of lower bandwidth or low data rate devices. Those devices may include, for example, floppy disks, parallel ports, keyboard and mouse, temperature sensor and fan speed monitoring, etc.

In some cases, IHS 700 may be configured to access different types of computer-accessible media separate from memory 712. Generally speaking, a computer-accessible medium may include any tangible, non-transitory storage media or memory media such as electronic, magnetic, or optical media—e.g., magnetic disk, a hard drive, a CD/DVD-ROM, a Flash memory, etc. coupled to IHS 700 via northbridge controller 704 and/or southbridge controller 716.

The terms “tangible” and “non-transitory,” as used herein, are intended to describe a computer-readable storage medium (or “memory”) excluding propagating electromagnetic signals; but are not intended to otherwise limit the type of physical computer-readable storage device that is encompassed by the phrase computer-readable medium or memory. For instance, the terms “non-transitory computer readable medium” or “tangible memory” are intended to encompass types of storage devices that do not necessarily store information permanently, including, for example, RAM. Program instructions and data stored on a tangible computer-accessible storage medium in non-transitory form may afterwards be transmitted by transmission media or signals such as electrical, electromagnetic, or digital signals, which may be conveyed via a communication medium such as a network and/or a wireless link.

A person of ordinary skill in the art will appreciate that IHS 700 is merely illustrative and is not intended to limit the scope of the disclosure described herein. In particular, any computer system and/or device may include any combination of hardware or software capable of performing certain operations described herein. In addition, the operations performed by the illustrated components may, in some embodiments, be performed by fewer components or distributed across additional components. Similarly, in other embodiments, the operations of some of the illustrated components may not be performed and/or other additional operations may be available.

For example, in some implementations, northbridge controller 704 may be combined with southbridge controller 716, and/or be at least partially incorporated into CPU(s) 702. In other implementations, one or more of the devices or components shown in FIG. 7 may be absent, or one or more other components may be added. Accordingly, systems and methods described herein may be implemented or executed with other computer system configurations.

A person of ordinary skill will recognize that IHS 700 of FIG. 7 is only one example of a system in which the certain embodiments may be utilized. Indeed, the embodiments described herein may be used in various electronic devices, such as network router devices, televisions, custom telecommunications equipment for special purpose use, etc. That is, certain techniques described herein are in no way limited to use with the IHS of FIG. 7.

It should be understood that various operations described herein may be implemented in software executed by processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. An information handling system (IHS) component immersion cooling system comprising:
a cold plate disposed on one or more IHS components of an IHS disposed in an immersion cooling tank; and
an immersible immersion fluid pump adapted to be deployed in the immersion cooling tank, the immersible immersion fluid pump in fluid flow communication with the cold plate, directing flow of immersion fluid in the immersion cooling tank to the cold plate.

2. The IHS component immersion cooling system of claim 1, wherein the immersible immersion fluid pump is disposed on the cold plate.

3. The IHS component immersion cooling system of claim 1, wherein the immersible immersion fluid pump is disposed in an equipment bay of the IHS.

4. The IHS component immersion cooling system of claim 3, wherein the cold plate is a first cold plate, the one or more IHS components are first one or more components and the immersible immersion fluid pump is a first immersible immersion fluid pump, and the IHS component immersion cooling system further comprises:
a second cold plate disposed on a second one or more IHS components;
a second immersible immersion fluid pump disposed in a second fan bay; and
a manifold adapted to distribute flow from the first and/or second immersible immersion fluid pump to the first and second cold plates.

5. The IHS component immersion cooling system of claim 1, wherein power is provided to the immersible immersion fluid pump via a fan power connection provided by the IHS.

6. The IHS component immersion cooling system of claim 1, wherein a pulse width modulation signal is provided to the immersible immersion fluid pump via a pulse width modulation connection provided by the IHS.

7. The IHS component immersion cooling system of claim 1, wherein the immersible immersion fluid pump is monitored via a tach signal provided from the immersible immersion fluid pump via a tach monitoring connection provided by the IHS.

8. The IHS component immersion cooling system of claim 1, further comprising tubing extending from an outlet of the cold plate away from other components of the IHS.

9. An information handling system (IHS) comprising:
a chassis configured to be at least partially disposed under a surface of an immersion fluid, the chassis comprising at least one component configured to be cooled by the immersion fluid in an immersion cooling tank during operation of the IHS;
a cold plate disposed on one or more of the at least one components to be cooled; and
an immersible immersion fluid pump adapted to be deployed in the immersion cooling tank, the immersible immersion fluid pump in fluid flow communication with the cold plate, directing flow of immersion fluid in the immersion cooling tank to the cold plate.

10. The IHS of claim 9, wherein the immersible immersion fluid pump is disposed on the cold plate.

11. The IHS of claim 9, wherein the immersible immersion fluid pump is disposed in an equipment bay of the IHS.

12. The IHS of claim 11, wherein the cold plate is a first cold plate, the one or more IHS components are first one or more components of the IHS and the immersible immersion fluid pump is a first immersible immersion fluid pump, and the IHS further comprises:
a second cold plate disposed on a second one or more IHS components of the IHS;
a second immersible immersion fluid pump disposed in a second fan bay; and
a manifold adapted to distribute flow from the first and/or second immersible immersion fluid pump to the first and second cold plates.

13. The IHS of claim 9, wherein power is provided to the immersible immersion fluid pump via a fan power connection provided by the IHS.

14. The IHS of claim 9, wherein a pulse width modulation signal is provided to the immersible immersion fluid pump via a pulse width modulation connection provided by the IHS.

15. The IHS of claim 9, wherein the immersible immersion fluid pump is monitored via a tach signal provided from the immersible immersion fluid pump via a tach monitoring connection provided by the IHS.

16. The IHS of claim 9 further comprising tubing extending from an outlet of the cold plate away from other components of the IHS.

17. A method for enhancing cooling of an information handling system (IHS) component in an immersion cooling tank, the method comprising:
disposing a cold plate on an IHS component of an IHS disposed in an immersion cooling tank; and
directing flow of immersion fluid in the immersion cooling tank to the cold plate by an immersible immersion fluid pump adapted to be deployed in the immersion cooling tank, via fluid flow communication between the immersible immersion fluid pump and the cold plate.

18. The method of claim 17, further comprising powering, controlling and/or monitoring the immersible immersion fluid pump via a fan power connection, a pulse width modulation connection, and/or a tach monitoring connection provided by the IHS.

19. The method of claim 17, wherein the cold plate is a first cold plate, the IHS component is a first component and the immersible immersion fluid pump is a first immersible immersion fluid pump, and the method further comprises:
disposing a second cold plate on a second IHS component; and
directing flow of immersion fluid in the immersion cooling tank to the first and/or second cold plate by the first, and a second, immersible immersion fluid pump deployed in the immersion cooling tank, via a manifold distributing flow from the first and/or second immersible immersion fluid pump to the first and second cold plates.

20. The method of claim 17 further comprising extending tubing from an outlet of the cold plate away from other components of the IHS and directing of the IHS.
